(19) United States
(12) Patent Application Publication
(10) Pub. No.: US 2023/0422578 A1
(43) Pub. Date: Dec. 28, 2023

(54) DISPLAY PANELS AND METHODS OF MANUFACTURING THE SAME, AND DISPLAY APPARATUSES

(71) Applicants: Chengdu BOE Optoelectronics Technology Co., Ltd., Chengdu, Sichuan (CN); BOE Technology Group Co., Ltd., Beijing (CN)

(72) Inventors: Kezhi LIU, Beijing (CN); Qian LI, Beijing (CN)

(21) Appl. No.: 18/038,896

(22) PCT Filed: Dec. 21, 2020
(86) PCT No.: PCT/CN2020/138072

§ 371 Date: May 25, 2023

(51) Int. Cl. H10K 59/80; H10K 59/12

(52) U.S. Cl. CPC H10K 59/80522; H10K 59/1201

(57) ABSTRACT

A display panel and a method of manufacturing the same, and a display apparatus. The display panel includes: a base substrate; a backplane circuit layer disposed on a side of the base substrate; a plurality of light-emitting units arranged at intervals on a side of the backplane circuit layer away from the base substrate, where each light-emitting unit includes an anode, a light-emitting layer, and a cathode arranged sequentially in a direction pointing away from the backplane circuit layer, and the cathodes in different light-emitting units are arranged at intervals, and the light-emitting layers in different light-emitting units are arranged at intervals; and an auxiliary cathode located between the base substrate and the cathodes, and electrically connected with the cathodes.

### CROSS-REFERENCE TO RELATED APPLICATIONS

This disclosure is the U.S. national phase of PCT Application No. PCT/CN2020/138072 filed on Dec. 21, 2020, the disclosure of which is incorporated herein by reference in its entirety.

### TECHNICAL FIELD

This disclosure relates to the field of display technology, and in particular to a display panel and a method of manufacturing the same, and a display apparatus.

### BACKGROUND

Organic light-emitting display devices have advantages such as high contrast, wide color gamut, wide field of view, and low power consumption, and are thus widely used in all aspects of production and life in modern society. Transparent organic light-emitting display devices have the following characteristics: objects behind them can be observed when they are not displaying, and image information can be displayed when they are displaying. The transparent organic light-emitting display devices have been widely used in smart homes, vehicle applications, military industry and other industries, and have more and more extensive application prospects. However, at present, transparent organic light-emitting displays still have challenges such as low light transmittance.

However, at present, there is still a lot of research to be done on display panels.

### SUMMARY

This disclosure is made based on the inventors' findings and knowledge of the following facts and issues.

The existing organic light-emitting display panel mostly uses an integral cathode, that is to say, a plurality of light-emitting units share a common cathode, and the inventors found that this arrangement is not conducive to improving the light transmittance of the display panel. While the use of patterned cathodes arranged at intervals for respective light-emitting units may lead to overloading of the entire display panel. The inventors found that by using patterned anodes, light-emitting layers, and cathodes, and connecting the cathodes to a metal layer or a conductive layer such as a source-drain electrode layer in a backplane circuit through an opening during formation of the cathodes, the loading of the entire display panel can be greatly reduced and the display effect of the display panel can be significantly improved while ensuring a relatively high light transmittance of the display panel. To this end, an objective of the present disclosure is to propose a display panel having patterned anodes, light-emitting layers, and cathodes, and the entire display panel has a relatively low loading and has a good display effect.

In an aspect of the present disclosure, the present disclosure provides a display panel. According to an embodiment of the present disclosure, the display panel includes: a base substrate; a backplane circuit layer disposed on a side of the base substrate; light-emitting units arranged at intervals on a side of the backplane circuit layer away from the base substrate, where each of the light-emitting units includes an anode, a light-emitting layer, and a cathode arranged sequentially in a direction pointing away from the backplane circuit layer, the cathodes in different light-emitting units are arranged at intervals, and the light-emitting layers in different light-emitting units are arranged at intervals; and an auxiliary cathode located between the base substrate and the cathodes, and electrically connected with the cathodes. Thus, the anodes, the light-emitting layers, and the cathodes in the display panel are all patterned, which helps to improve the flexibility of the display panel such that the entire display panel are rollable arbitrarily, in the case that the display panel is a flexible display panel. Moreover, in the display panel, the cathodes in different light-emitting units are arranged at intervals, and the light-emitting layers in different light-emitting units are arranged at intervals, that is, the display panel includes a plurality of patterned cathodes and a plurality of patterned light-emitting layers, which can effectively improve the light transmittance of the display panel and is conducive to the design of a transparent display. The entire display panel may have a relatively high loading due to patterning of the cathode layer, while electrically connecting the cathodes with the auxiliary cathode can greatly reduce the loading of the display panel and improve the display quality.

According to an embodiment of the present disclosure, the auxiliary cathode is a part of a source-drain electrode layer of the backplane circuit layer.

According to an embodiment of the present disclosure, an orthographic projection of the anode onto the base substrate is located within an orthographic projection of the cathode onto the base substrate, and an orthographic projection of the auxiliary cathode onto the base substrate is located within the orthographic projection of the cathode onto the base substrate.

According to an embodiment of the present disclosure, each of the light-emitting units further includes a hole injection layer, a hole transport layer, an electron transport layer, and an electron injection layer, where the hole injection layer is disposed between the anode and the light-emitting layer, the hole transport layer is disposed between the hole injection layer and the light-emitting layer, the electron transport layer is disposed between the light-emitting layer and the cathode, and the electron injection layer is disposed between the electron transport layer and the cathode. The hole injection layers in different light-emitting units are arranged at intervals, the hole transport layers in different light-emitting units are arranged at intervals, the electron transport layers in different light-emitting units are arranged at intervals, and the electron injection layers in different light-emitting units are arranged at intervals.

According to an embodiment of the present disclosure, each of the light-emitting units includes sub-light-emitting units, each of which includes a sub-cathode, a sub-anode, and a sub-light-emitting layer disposed between the sub-cathode and the sub-anode. In each of the light-emitting units, the sub-anodes in different sub-light-emitting units are arranged at intervals, the sub-light-emitting layers in different sub-light-emitting units are arranged at intervals, and the sub-cathodes in different sub-light-emitting units are joined with each other to form the cathode.

According to an embodiment of the present disclosure, each of the sub-light-emitting units further includes a sub-hole injection layer, a sub-hole transport layer, a sub-electron transport layer, and a sub-electron injection layer, where the sub-hole injection layer is disposed between the sub-anode and the sub-light-emitting layer, the sub-hole transport layer is disposed between the sub-hole injection layer and the sub-light-emitting layer, the sub-electron transport layer is disposed between the sub-light-emitting layer and the sub-cathode, and the sub-electron injection layer is disposed between the sub-electron transport layer and the sub-cathode. In each of the light-emitting units, the sub-hole injection layers in different sub-light-emitting units are arranged at intervals, the sub-hole transport layers in different sub-light-emitting units are arranged at intervals, the sub-electron transport layers in different sub-light-emitting units are arranged at intervals, and the sub-electron injection layers in different sub-light-emitting units are arranged at intervals.

According to an embodiment of the present disclosure, each of the sub-light-emitting units further includes a sub-hole injection layer, a sub-hole transport layer, a sub-electron transport layer, and a sub-electron injection layer, where the sub-hole injection layer is disposed between the sub-anode and the sub-light-emitting layer, the sub-hole transport layer is disposed between the sub-hole injection layer and the sub-light-emitting layer, the sub-electron transport layer is disposed between the sub-light-emitting layer and the sub-cathode, and the sub-electron injection layer is disposed between the sub-electron transport layer and the sub-cathode. In each of the light-emitting units, the sub-hole injection layers in different sub-light-emitting units are joined with each other, the sub-hole transport layers in different sub-light-emitting units are joined with each other, the sub-electron injection layers in different sub-light-emitting units are joined with each other, and the sub-electron transport layers in different sub-light-emitting units are joined with each other.

According to an embodiment of the present disclosure, in each of the light-emitting units, a distance between the sub-anodes in adjacent two of the sub-light-emitting units is 5 μm to 15 μm.

According to an embodiment of the present disclosure, the display panel further includes: a bridge connecting the cathodes in adjacent two of the light-emitting units, and arranged in a same layer as the cathodes.

According to an embodiment of the present disclosure, the bridge is elongated in shape, and has a width of 50 μm to 70 μm.

According to an embodiment of the present disclosure, an orthographic projection of the auxiliary cathode onto the base substrate is located within an orthographic projection of the bridge onto the base substrate.

According to an embodiment of the present disclosure, the backplane circuit layer includes: an active layer disposed on the side of the base substrate; a gate insulation layer disposed on a side of the active layer away from the base substrate; a gate electrode disposed on a side of the gate insulation layer away from the active layer; an interlayer dielectric layer disposed on a side of the gate electrode away from the base substrate, and covering a surface of the gate insulation layer that is not covered by the gate electrode; a source-drain electrode layer disposed on a side of the interlayer dielectric layer away from the base substrate, and electrically connected with the active layer; and a planarization layer disposed on a side of the source-drain electrode layer away from the base substrate, and covering a surface of the interlayer dielectric layer that is not covered by the source-drain electrode layer, where the planarization layer is made of colorless polyimide.

According to an embodiment of the present disclosure, the light-emitting units are arranged in an array, where among the light-emitting units in a same row, a distance between two adjacent light-emitting units is equal to a width of the light-emitting unit in a row direction, and among the light-emitting units in a same column, a distance between two adjacent light-emitting units is equal to a width of the light-emitting unit in a column direction.

In another aspect of the present disclosure, the present disclosure provides a method of manufacturing a display panel. According to an embodiment of the present disclosure, the method of manufacturing the display panel includes: preparing a backplane circuit layer on a side of a base substrate; forming light-emitting units arranged at intervals on a side of the backplane circuit layer away from the base substrate, where forming the light-emitting units includes: forming anodes on the side of the backplane circuit layer away from the base substrate; forming light-emitting layers on a side of the anodes away from the backplane circuit layer; and forming cathodes on a side of the light-emitting layers away from the anodes, where the cathodes in different light-emitting units are arranged at intervals, and the light-emitting layers in different light-emitting units are arranged at intervals; and forming an auxiliary cathode between the base substrate and the cathodes, and electrically connecting the auxiliary cathode with the cathodes. Thus, the anodes, the light-emitting layers, and the cathodes in the display panel are all patterned, which helps to improve the flexibility of the display panel such that the entire display panel are rollable arbitrarily, in the case that the display panel is a flexible display panel. Moreover, in the display panel, the cathodes in different light-emitting units are arranged at intervals, and the light-emitting layers in different light-emitting units are arranged at intervals, that is, the display panel includes a plurality of patterned cathodes and a plurality of patterned light-emitting layers, which can effectively improve the light transmittance of the display panel and is conducive to the design of a transparent display. The entire display panel may have a relatively high loading due to patterning of the cathode layer, while electrically connecting the auxiliary cathode with the cathodes can greatly reduce the loading of the display panel and improve the display quality. Furthermore, the above method is simple and easy to implement, and is convenient for industrialized production.

According to an embodiment of the present disclosure, forming the light-emitting units includes: forming sub-anodes arranged at intervals on the side of the backplane circuit layer away from the base substrate; forming sub-light-emitting layers arranged at intervals on a side of the sub-anodes away from the backplane circuit layer; and forming sub-cathodes on a side of the sub-light-emitting layers away from the sub-anodes, the sub-cathodes being joined with each other to form the cathodes.

According to an embodiment of the present disclosure, the auxiliary cathode is electrically connected with the cathodes through a connecting wire, the anodes and the light-emitting layers are formed by evaporation using a patterned mask, and the cathodes and the connecting wire are formed simultaneously by evaporation using a patterned mask.

According to an embodiment of the present disclosure, the method of manufacturing the display panel further includes: forming a bridge in a same step as the cathodes to connect the cathodes in adjacent two of the light-emitting units.

In yet another aspect of the present disclosure, the present disclosure provides a display apparatus. According to an embodiment of the present disclosure, the display apparatus includes the display panel as described above or the display panel manufactured by the method as described above. Thus, the display apparatus has a good display effect and a relatively low loading. Those skilled in the art understand that the display apparatus has all the features and advantages of the display panel as described above, which will not be repeated herein.

### BRIEF DESCRIPTION OF DRAWINGS

FIG. 1 is a schematic structural diagram illustrating a display panel according to an embodiment of the present disclosure.

FIG. 2 is a schematic structural diagram illustrating a display panel according to another embodiment of the present disclosure.

FIG. 3 is a schematic structural diagram illustrating a display panel according to yet another embodiment of the present disclosure.

FIG. 4 is a schematic structural diagram illustrating a display panel according to yet another embodiment of the present disclosure.

FIG. 5 is a schematic structural diagram illustrating a display panel according to yet another embodiment of the present disclosure.

FIG. 6 is a schematic diagram illustrating a partial structure of a display panel according to yet another embodiment of the present disclosure.

FIG. 7 is a schematic plan view illustrating a partial structure of a display panel according to yet another embodiment of the present disclosure.

FIG. 8 is a schematic plan view illustrating a partial structure of a display panel according to yet another embodiment of the present disclosure.

FIG. 9 is a schematic structural diagram illustrating a partial structure of a display panel according to yet another embodiment of the present disclosure.

FIG. 10 is a schematic diagram illustrating arrangement of light-emitting units according to yet another embodiment of the present disclosure.

### DETAILED DESCRIPTION

Embodiments of the present disclosure will be described in detail below. The embodiments described below are exemplary, and are intended only to explain the present disclosure and are not to be construed as limiting the present disclosure. Where specific techniques or conditions are not indicated in an embodiment, the techniques or conditions described in literature in the art or in the product specification are followed.

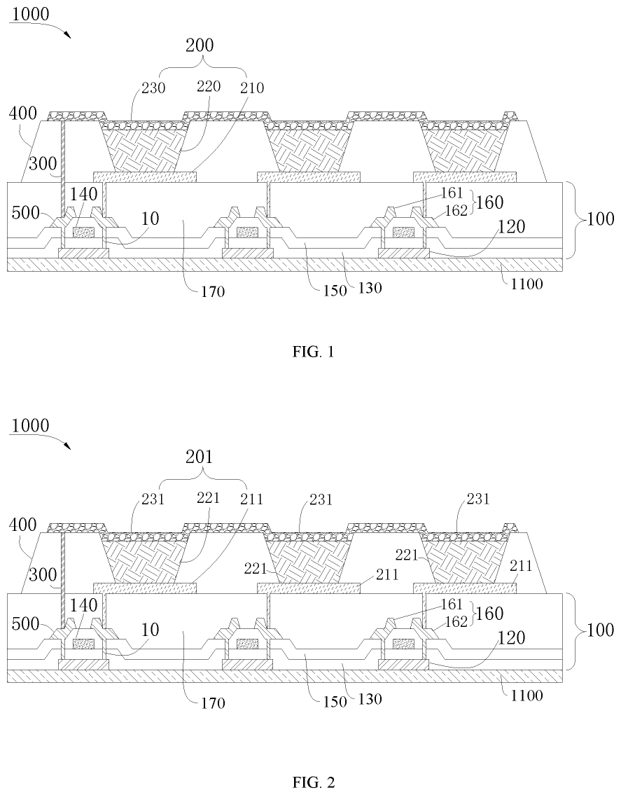

In an aspect of the present disclosure, the present disclosure provides a display panel. According to an embodiment of the present disclosure, and referring to FIGS. 1 to 5 in which only one light-emitting unit is illustrated, the display panel 1000 includes: a base substrate 1100; a backplane circuit layer 100 disposed on a side of the base substrate 1100; a plurality of light-emitting units 200 arranged at intervals or spaced apart on a side of the backplane circuit layer 100 away from the base substrate 1100, where each of the light-emitting units 200 includes an anode 210, a light-emitting layer 220, and a cathode 230 arranged sequentially in a direction pointing away from the backplane circuit layer 100, the cathodes 230 in different light-emitting units 200 are arranged at intervals, and the light-emitting layers 220 in different light-emitting units 200 are arranged at intervals; and an auxiliary cathode 500 located between the base substrate 1100 and the cathodes 230, and electrically connected with the cathodes 230. In some specific embodiments, the auxiliary cathode 500 is electrically connected with the cathodes 230 through a connecting wire 300. Thus, the anodes, the light-emitting layers, and the cathodes in the display panel are all patterned, which helps to improve the flexibility of the display panel such that the entire display panel are rollable arbitrarily, in the case that the display panel is a flexible display panel. Moreover, in the display panel, the cathodes in different light-emitting units are arranged at intervals, and the light-emitting layers in different light-emitting units are arranged at intervals, that is, the display panel includes a plurality of patterned cathodes and a plurality of patterned light-emitting layers, which can effectively improve the light transmittance of the display panel and is conducive to the design of a transparent display. The entire display panel may have a relatively high loading due to patterning of the cathode layer, while electrically connecting the cathodes with the auxiliary cathode can greatly reduce the loading of the display panel and improve the display quality.

It should be noted that the auxiliary cathode can be any conductive layer or metal layer between the base substrate and the cathodes, and when the auxiliary cathode is electrically connected with the cathodes, it is beneficial to reduce the loading of the display panel. In some embodiments, referring to FIGS. 1 to 5, the auxiliary cathode 500 is a part of a source-drain electrode layer. In this case, the auxiliary cathode 500 is electrically connected with the cathodes 230 through the connecting wire 300, and at this time, the cathodes do not need to be further electrically connected with a VSS signal line. That is to say, the cathodes are electrically connected with the auxiliary cathode which is a part of the source-drain electrode layer through the connecting wire 300, instead of electrically connecting the cathodes with the VSS signal line, so as to ensure that the cathodes function effectively, and in turn ensure that the light-emitting units emit light normally. It should be noted that, since the source-drain electrode layer includes multiple wirings such as source electrodes, drain electrodes, data lines (Vd), power signal lines or other signal lines, the auxiliary cathode is a part of the source-drain electrode layer, which refers to any structure of the multiple wirings such as source electrodes, drain electrodes, data lines (Vd), power signal lines or other signal lines, and can be selected flexibly by those skilled in the art according to the actual situations, as long as the electrical connection effect can be effectively achieved without affecting the operation and arrangement of individual wirings. By way of example only, the cathodes 230 are electrically connected to a source electrode 161 in a source-drain electrode layer 160 through the connecting wire 300 in FIGS. 1 to 5, and the cathodes 230 are electrically connected to a certain signal line in the source-drain electrode layer 160 through the connecting wire 300 in FIG. 6.

According to an embodiment of the present disclosure, and referring to FIGS. 1 to 5, an orthographic projection of the anode onto the base substrate is located within an orthographic projection of the cathode onto the base substrate, and an orthographic projection of the auxiliary cathode onto the base substrate is located within the orthographic projection of the cathode onto the base substrate. In this way, it is conducive to providing bridging holes for the electrical connection between the auxiliary cathode and the cathodes, which helps to improve the overall performance of the display panel.

According to an embodiment of the present disclosure, there are no special requirements for the specific structure of the backplane circuit layer, which can be selected flexibly by those skilled in the art according to the actual situations. In some embodiments, referring to FIGS. 1 to 5, the backplane circuit layer 100 includes: an active layer 120 disposed on the side of the base substrate 1100; a gate insulation layer 130 disposed on a side of the active layer 120 away from the base substrate 1100; a gate electrode 140 disposed on a side of the gate insulation layer 130 away from the active layer 120; an interlayer dielectric layer 150 disposed on a side of the gate electrode 140 away from the base substrate 1100, and covering a surface of the gate insulation layer 130 that is not covered by the gate electrode 140; a source-drain electrode layer 160 disposed on a side of the interlayer dielectric layer 150 away from the base substrate 1100, and electrically connected with the active layer 120 through a through hole 10, the source-drain electrode layer 160 including a source electrode 161 and a drain electrode 162; and a planarization layer 170 disposed on a side of the source-drain electrode layer 160 away from the base substrate 1100, and covering a surface of the interlayer dielectric layer 150 that is not covered by the source-drain electrode layer 160, where the planarization layer 170 is made of colorless polyimide. Both the base substrate 1100 and the planarization layer 170 are made of colorless polyimide (CPI), which can greatly improve the light transmittance of the display panel, and in turn facilitates the design of a transparent display panel.

However, those skilled in the art can understand that the backplane circuit layer may include other conventional structures in addition to the above structure, such as a buffer layer disposed between the active layer and the base substrate, a barrier layer disposed between the buffer layer and the base substrate, and the structure of storage capacitors, which will not be described in detail herein.

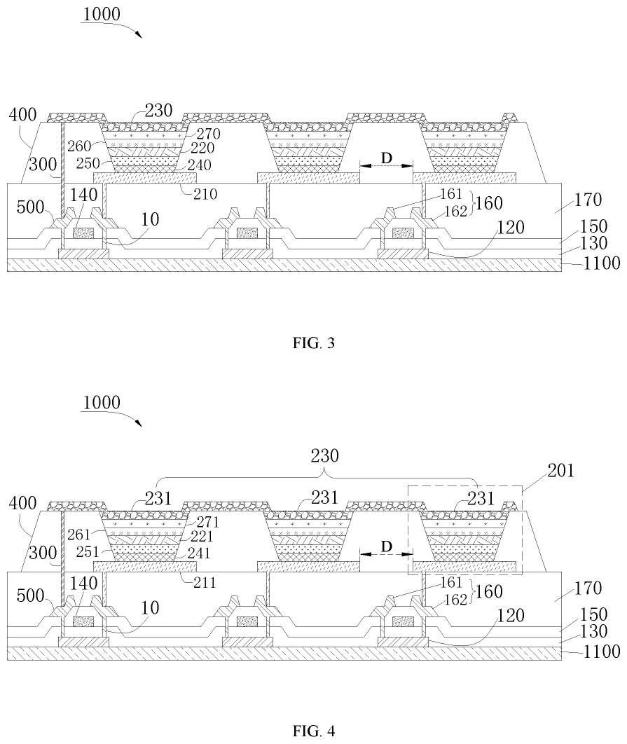

According to an embodiment of the present disclosure, and referring to FIG. 1, FIG. 3 and FIG. 4, the light-emitting unit may further include a hole injection layer 240, a hole transport layer 250, an electron transport layer 260, and an electron injection layer 270. The hole injection layer 240 is disposed between the anode 210 and the light-emitting layer 220, the hole transport layer 250 is disposed between the hole injection layer 240 and the light-emitting layer 220, the electron transport layer 260 is disposed between the light-emitting layer 220 and the cathode 230, and the electron injection layer 270 is disposed between the electron transport layer 260 and the cathode 230. The hole injection layers 240 in different light-emitting units 200 are arranged at intervals, the hole transport layers 250 in different light-emitting units 200 are arranged at intervals, the electron transport layers 260 in different light-emitting units 200 are arranged at intervals, and the electron injection layers 270 in different light-emitting units 200 are arranged at intervals. In this way, it is beneficial to improve the performance of the light-emitting units in use.

According to an embodiment of the present disclosure, and referring to FIGS. 1 to 4, the light-emitting unit 200 includes a plurality of sub-light-emitting units 201, where only one light-emitting unit 200 that includes three sub-light-emitting units 201 is illustrated in FIGS. 1 to 4 as an example. Each sub-light-emitting unit 201 includes a sub-cathode 231, a sub-anode 211, and a sub-light-emitting layer 221 disposed between the sub-cathode and the sub-anode. In the same light-emitting unit 200, the sub-anodes 211 in different sub-light-emitting units 201 are arranged at intervals, the sub-light-emitting layers 221 in different sub-light-emitting units 201 are arranged at intervals, and the sub-cathodes 231 in different sub-light-emitting units 201 are joined with each other to form the cathode, that is, a plurality of sub-cathodes 231 in different sub-light-emitting units 201 together form the cathode. In other words, in the same light-emitting unit, the sub-anodes are independent of each other, and the sub-light-emitting layers are independent of each other, but the sub-cathodes are in contact with each other to form an integral layer of cathode structure, and cover the sub-light-emitting layers in the plurality of sub-light-emitting units.

According to an embodiment of the present disclosure, there are no special requirements for the number of sub-light-emitting units included in each light-emitting unit, which can be designed flexibly by those skilled in the art according to the actual situations. In some embodiments, each light-emitting unit includes three sub-light-emitting units 201, i.e., a red sub-light-emitting unit, a green sub-light-emitting unit, and a blue sub-light-emitting unit.

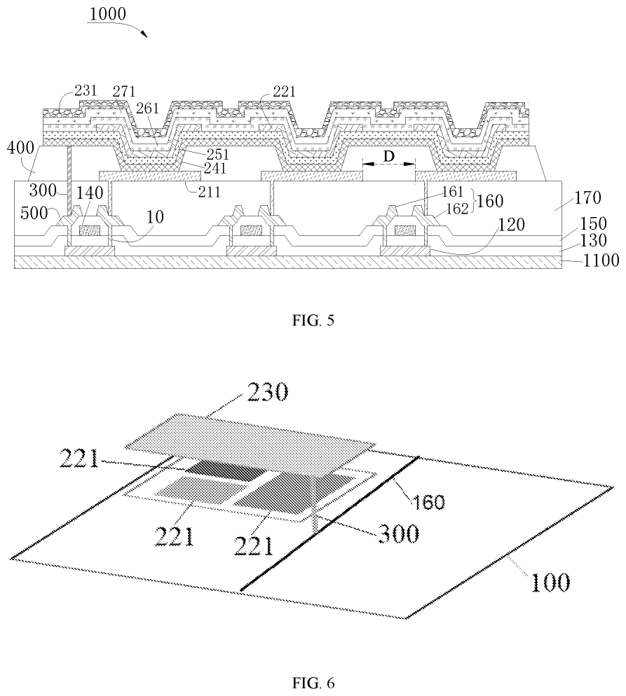

According to some embodiments of the present disclosure, and referring to FIGS. 4 and 5, the sub-light-emitting unit 201 may further include a sub-hole injection layer 241, a sub-hole transport layer 251, a sub-electron transport layer 261, and a sub-electron injection layer 271, where the sub-hole injection layer 241 is disposed between the sub-anode 211 and the sub-light-emitting layer 221, the sub-hole transport layer 251 is disposed between the sub-hole injection layer 241 and the sub-light-emitting layer 221, the sub-electron transport layer 261 is disposed between the sub-light-emitting layer 221 and the sub-cathode 231, and the sub-electron injection layer 271 is disposed between the sub-electron transport layer 261 and the sub-cathode 231. The sub-hole injection layer 241, the sub-hole transport layer 251, the sub-electron transport layer 261, and the sub-electron injection layer 271 may meet one of the following conditions.

In some embodiments, referring to FIG. 4, in the same light-emitting unit 200, the sub-hole injection layers 241 in different sub-light-emitting units 201 are arranged at intervals, the sub-hole transport layers 251 in different sub-light-emitting units 201 are arranged at intervals, the sub-electron transport layers 261 in different sub-light-emitting units 201 are arranged at intervals, and the sub-electron injection layers 271 in different sub-light-emitting units 201 are arranged at intervals. Thus, the sub-hole injection layers 241, the sub-hole transport layers 251, the sub-electron transport layers 261, and the sub-electron injection layers 271 in different sub-light-emitting units 201 are all arranged at intervals, which can further improve the flexibility and bendability of the display panel and facilitate independent control of the light emission of different sub-light-emitting units. In some embodiments, the maximum rollable angle of the display panel can reach 360°.

In alternative embodiments, referring to FIG. 5, in the same light-emitting unit 200, the sub-hole injection layers 241 in different sub-light-emitting units 201 are joined with each other, the sub-hole transport layers 251 in different sub-light-emitting units 201 are joined with each other, the sub-electron transport layers 261 in different sub-light-emitting units 201 are joined with each other, and the sub-electron injection layers 271 in different sub-light-emitting units 201 are joined with each other. Thus, the display panel can also realize the display function, and since the hole injection layers 240, the hole transport layers 250, the electron transport layers 260, and the electron injection layers 270 in different light-emitting units are all arranged at intervals, the above structure in FIG. 5 can still effectively improve the flexibility and bendability of the display panel.

Furthermore, as shown in FIGS. 1 to 5, the display panel further includes a pixel definition layer 400 disposed on a side of the planarization layer 170 away from the base substrate 1100. The pixel definition layer 400 defines a plurality of openings, in which the sub-light-emitting units 201 are disposed.

According to an embodiment of the present disclosure, the connecting wire and the cathode are of an integrated structure, i.e., the connecting wire and the cathode are manufactured in the same process step, such that the process flow can be simplified and the process time can be shortened. The material for forming the cathode and the connecting wire includes, but is not limited to, a conductive oxide or metal material such as IZO, Al, and Mg.

According to an embodiment of the present disclosure, the material for forming the anode includes, but is not limited to, ITO/Ag/ITO. The material for forming the active layer includes, but is not limited to, IGZO, ZnON, ITZO, and low temperature poly-silicon. The material for forming the gate electrode includes, but is not limited to, a metal material such as aluminium, molybdenum, chromium, copper, and titanium. The material for forming the source-drain electrode layer includes, but is not limited to, a metal material such as aluminium, molybdenum, chromium, copper, and titanium. The material for forming the gate insulation layer and the interlayer dielectric layer includes, but is not limited to, an insulating material such as silicon nitride, silicon oxide, and silicon oxynitride.

According to an embodiment of the present disclosure, and referring to FIGS. 3 to 5, in the same light-emitting unit, a distance D between the sub-anodes 211 in adjacent two of the sub-light-emitting units 201 is 5 μm to 15 μm, e.g., 5 μm, 7 μm, 9 μm, 10 μm, 11 μm, 13 μm, or 15 μm. Thus, when the connecting wire 300 electrically connects the cathode and the auxiliary cathode through a gap between the sub-light-emitting units 201, the above distance can meet the design of a bridging hole for the electrical connection between the auxiliary cathode and the cathode, enabling an effective electrical connection.

There are no special requirements for the specific position of the bridging hole where the cathode 230 is electrically connected with the auxiliary cathode 500 between the base substrate 1100 and the cathode 230 through the connecting wire 300, which can be selected flexibly by those skilled in the art according to the actual situations, as long as the electrical connection between the cathode and the auxiliary cathode can be achieved without affecting the arrangement of individual wirings in the display panel, where the connecting wire 300 is disposed in the bridging hole.

According to an embodiment of the present disclosure, and referring to FIGS. 6 and 7, the cathodes 230 in different light-emitting units are arranged at intervals, and the cathode 230 in each light-emitting unit covers the light-emitting layer 220, that is, the cathode 230 covers the plurality of sub-light-emitting layers in the plurality of sub-light-emitting units. In the structure shown in FIGS. 6 and 7, the bridging hole 800 or the connecting wire 300 is located outside the light-emitting layer 220, where the connecting wire 300 achieves the electrical connection between the auxiliary cathode and the cathode through the bridging hole 800, and the orthographic projection of the auxiliary cathode 500 onto the base substrate is located within the orthographic projection of the cathode 230 onto the base substrate.

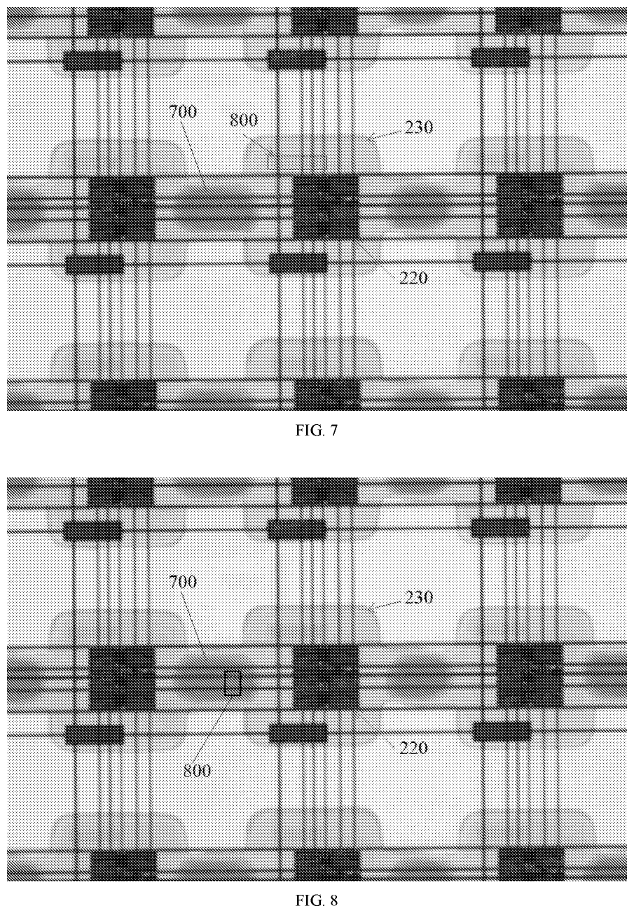

Referring to FIGS. 7 and 8, the display panel further includes: a bridge 700 connecting the cathodes 230 in adjacent two of the light-emitting units 200, and arranged in the same layer as the cathodes, which is conducive to reducing the loading of the display panel. According to some specific embodiments of the present disclosure, and referring to FIG. 7 or FIG. 8, adjacent cathodes 230 in multiple light-emitting units in the same row or in the same column are electrically connected with each other through the bridge 700, and the bridge 700 is arranged in the same layer as the cathodes 230.

Furthermore, when the auxiliary cathode is a part of the source-drain electrode layer, one of the cathodes 230 in the light-emitting units in each row or each column is electrically connected with the auxiliary cathode through the bridge 700, and may be further electrically connected with the VSS signal line. The electrical connection between the cathode and the VSS signal line can play the role of prevention and repair, that is, in the case of an electrical connection failure between one or more auxiliary cathodes and the cathode, the effective function of the cathode can be effectively ensured due to the electrical connection between the cathode and the VSS signal line, so as to prevent the corresponding light-emitting unit from not emitting light properly.

Furthermore, as shown in FIG. 8, an orthographic projection of the bridging hole 800 where the connecting wire is electrically connected with the cathode onto the base substrate is located within an orthographic projection of the bridge 700 onto the base substrate. In this way, it is conducive to setting the position of the bridging hole without affecting the arrangement of wirings in the display panel, and is conducive to improving the performance of the display panel in use.

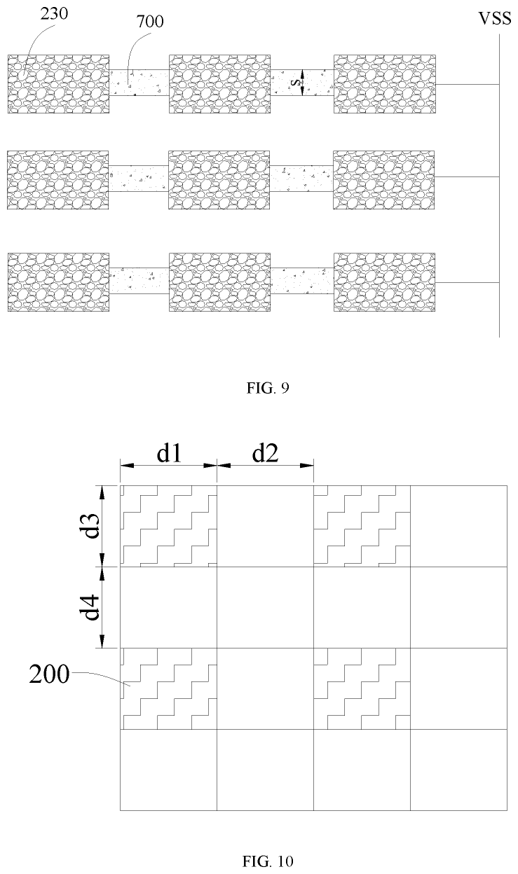

According to an embodiment of the present disclosure, and referring to FIG. 9, the bridge 700 is elongated in shape, and has a width S of 50 μm to 70 μm, e.g., 50 μm, 55 μm, 60 μm, 65 μm, 70 μm. Setting the width of the bridge within the above width range can ensure that the light transmittance of the display panel may not be greatly affected, while enabling relatively low loading of the display panel. If the width of the bridge is too small, the display panel may have a relatively high loading; and if the width of the bridge is too large, the display panel may have a relatively low light transmittance, which is not conducive to the design of a transparent display.

According to an embodiment of the present disclosure, and referring to FIG. 8, an orthographic projection of the auxiliary cathode (not shown in FIG. 8) onto the base substrate is located within an orthographic projection of the bridge onto the base substrate. FIG. 8 shows a plan view, and the auxiliary cathode and the cathode are not arranged in the same layer. It can be understood by those skilled in the art that the auxiliary cathode may be connected to multiple cathodes through the bridge, which includes but is not limited to connecting the auxiliary cathode to the cathode through the bridge by forming a via. Thus, it is beneficial to reduce the loading of the display panel.

According to an embodiment of the present disclosure, when the display panel is used in a transparent display, the pixel density (PPI, pixels per inch) of the display panel is reduced compared to a conventional display panel in order to further improve the light transmittance of the display panel, that is, for a display panel with a certain size, the size between two adjacent light-emitting units 200 is increased. In some embodiments, among multiple light-emitting units in the same row, a distance d2 between two adjacent light-emitting units is equal to a width dl of the light-emitting unit in a row direction (i.e., d2=d1); and among multiple light-emitting units in the same column, a distance d4 between two adjacent light-emitting units is equal to a width d3 of the light-emitting unit in a column direction (i.e., d4=d3), as shown in FIG. 10. However, it can be understood by those skilled in the art that, neither a light-emitting unit nor a pixel circuit is disposed in a gap between two adjacent light-emitting units.

In another aspect of the present disclosure, the present disclosure provides a method of manufacturing a display panel. The method of manufacturing the display panel includes steps S100 to S400.

At step S100, a base substrate 1100 is provided.

The base substrate 1100 is provided, where the base substrate may be made of colorless polyimide, such that the light transmittance of the display panel can be improved.

At step S200, a backplane circuit layer 100 is prepared on a side of the base substrate 1100.

In some embodiments, preparing the backplane circuit layer 100 includes: forming an active layer 120 on the side of the base substrate 1100; forming a gate insulation layer 130 on a side of the active layer 120 away from the base substrate 1100; forming a gate electrode 140 on a side of the gate insulation layer 130 away from the active layer 120; forming an interlayer dielectric layer 150 on a side of the gate electrode 140 away from the base substrate 1100, to cover a surface of the gate insulation layer 130 that is not covered by the gate electrode 140; forming a source-drain electrode layer 160 on a side of the interlayer dielectric layer 150 away from the base substrate 1100, and electrically connecting the source-drain electrode layer 160 with the active layer 120 through a through hole 10, where the source-drain electrode layer 160 includes a source electrode 161 and a drain electrode 162; and forming a planarization layer 170 on a side of the source-drain electrode layer 160 away from the base substrate 1100, to cover a surface of the interlayer dielectric layer 150 that is not covered by the source-drain electrode layer 160, where the planarization layer 170 is made of colorless polyimide. The schematic structural diagrams of the resulting display panel can be found in FIGS. 1 to 5. Both the base substrate 1100 and the planarization layer 170 are made of colorless polyimide, which can greatly improve the light transmittance of the display panel, and in turn facilitates the design of a transparent display panel.

At step S300, a plurality of light-emitting units 200 arranged at intervals are formed on a side of the backplane circuit layer 100 away from the base substrate 1100.

Forming the plurality of light-emitting units includes: forming anodes 210 on the side of the backplane circuit layer 100 away from the base substrate 1100; forming light-emitting layers 220 on a side of the anodes 210 away from the backplane circuit layer 100; and forming cathodes 230 on a side of the light-emitting layers 220 away from the anodes, where the cathodes 230 in different light-emitting units 200 are arranged at intervals. The schematic structural diagrams of the resulting display panel can be found in FIGS. 1 to 5.

According to an embodiment of the present disclosure, and referring to FIGS. 1 to 4, the light-emitting unit includes a plurality of sub-light-emitting units 201 arranged at intervals, where one light-emitting unit 200 that includes three sub-light-emitting units 201 is illustrated in FIGS. 1 to 4 as an example. Forming the plurality of light-emitting units includes: forming a plurality of sub-anodes 211 arranged at intervals on the side of the backplane circuit layer 100 away from the base substrate 1100; forming a plurality of sub-light-emitting layers 221 arranged at intervals on a side of the sub-anodes 211 away from the backplane circuit layer 100; and forming a plurality of sub-cathodes 231 on a side of the sub-light-emitting layers 221 away from the sub-anodes 211, the plurality of sub-cathodes 231 being joined with each other to form the cathodes 230. In other words, in the same light-emitting unit, the sub-anodes are independent of each other, and the sub-light-emitting layers are independent of each other, but the sub-cathodes are in contact with each other to form an integral layer of cathode structure, and cover the sub-light-emitting layers in the plurality of sub-light-emitting units.

According to an embodiment of the present disclosure, the anodes and the light-emitting layers are formed by evaporation using a patterned mask. There are no special requirements for the specific shape of the pattern on the mask, which can be selected flexibly by those skilled in the art according to the actual situation such as the shape of the effective light-emitting area of the sub-light-emitting unit or the shape of the opening defined in the pixel definition layer, and can be quadrilateral, circular, elliptical, hexagonal, pentagonal, or irregular shape, for example.

At step S400, an auxiliary cathode 500 is formed between the base substrate 1100 and the cathodes 230, and is electrically connected with the cathodes 230. It should be noted that the auxiliary cathode can be any conductive layer or metal layer between the base substrate and the cathodes, and when the auxiliary cathode is electrically connected with the cathodes, it is beneficial to reduce the loading of the display panel. In some specific embodiments, the auxiliary cathode is electrically connected with the cathodes through a connecting wire. In FIGS. 1 to 5, by way of example only, a part of the source-drain electrode layer 160 is used as the auxiliary cathode, to electrically connect the cathodes 230 with a source electrode 161 in the source-drain electrode layer through the connecting wire 300. Further, the cathodes 230 and the connecting wire 300 are formed simultaneously by evaporation using a patterned mask, i.e., the cathodes and the connecting wire are manufactured by the same process step, which in turn simplifies the process flow and shortens the process time.

Since the source-drain electrode layer includes multiple wirings such as source electrodes, drain electrodes, data lines (Vd), power signal lines or other signal lines, when the cathode 230 is electrically connected with the source-drain electrode layer 160 through the connecting wire 300, any of the wirings can be selected flexibly by those skilled in the art according to the actual situations, as long as the electrical connection effect can be effectively achieved without affecting the operation and arrangement of individual wirings. By way of example only, the cathodes 230 are electrically connected to the source electrode 161 in the source-drain electrode layer 160 through the connecting wire 300 in FIGS. 1 to 5, and the cathodes 230 are electrically connected to a certain signal line in the source-drain electrode layer 160 through the connecting wire 300 in FIG. 6.

Furthermore, there are no special requirements for the specific position of a bridging hole where the cathode 230 is electrically connected with the auxiliary cathode through the connecting wire 300, which can be selected flexibly by those skilled in the art according to the actual situations, as long as the electrical connection between the cathode and the auxiliary cathode can be achieved without affecting the arrangement of individual wirings in the display panel.

According to an embodiment of the present disclosure, the method of manufacturing the display panel further includes forming a bridge 700 in the same step as the cathodes 230 to connect the cathodes 230 in adjacent two of the light-emitting units 200. The bridge is arranged in the same layer as the cathodes, which is beneficial to reduce the loading of the display panel.

Furthermore, when the auxiliary cathode is a part of the source-drain electrode layer, one of the cathodes 230 in the light-emitting units in each row or each column is electrically connected with the auxiliary cathode through the bridge 700, and may be further electrically connected with the VSS signal line, as shown in FIG. 7 or FIG. 8. In this way, the electrical connection between the cathode and the VSS signal line can play the role of prevention and repair, that is, in the case of an electrical connection failure between one or more auxiliary cathodes and the cathode, the effective function of the cathode can be effectively ensured due to the electrical connection between the cathode and the VSS signal line, so as to prevent the corresponding light-emitting unit from not emitting light properly.

According to an embodiment of the present disclosure, the above method of manufacturing the display panel may be configured to manufacture the display panel as described above. During the process of manufacturing the display panel, the requirements for providing the structure such as the base substrate, backplane circuit layer, anode, light-emitting layer, or cathode are the same as those for the structure of each layer in the display panel as described above, and will not be repeated herein.

In yet another aspect of the present disclosure, the present disclosure provides a display apparatus. According to an embodiment of the present disclosure, the display apparatus includes the display panel as described above or the display panel manufactured by the method as described above. Thus, the display apparatus has a good display effect, a relatively low loading, and a better rollable effect. Those skilled in the art understand that the display apparatus has all the features and advantages of the display panel as described above, which will not be repeated herein.

According to an embodiment of the present disclosure, there are no special requirements for the specific type of the above display apparatus, which can be selected flexibly by those skilled in the art according to the actual needs. For example, the display apparatus may be a mobile phone, iPad, notebook computer, or the like.

Those skilled in the art can understand that, the display apparatus has structures and components necessary for a conventional display apparatus, in addition to the above-mentioned display panel. For example, in the case of a mobile phone, it includes a rear battery cover, a middle frame, a touch panel, an audio module, a mainboard and other necessary structures and components, in addition to the above-mentioned display panel.

In the description of this specification, reference to terms “an embodiment,” “some embodiments,” “some specific embodiments,” or “other specific embodiments,” and the like means that specific features, structures, materials, or characteristics described in connection with the embodiment or example are included in at least one embodiment or example of the present disclosure. In this specification, the schematic representations of the above terms are not necessarily directed to the same embodiment or example. Moreover, the specific features, structures, materials, or characteristics as described may be combined in a suitable manner in any one or more embodiments or examples. In addition, those skilled in the art may combine different embodiments or examples described in this specification and features in different embodiments or examples without conflicting with each other.

Although the embodiments of the present disclosure have been shown and described above, it can be understood that the above embodiments are exemplary and are not to be construed as limiting the present disclosure, and that changes, modifications, substitutions, and variations may be made to the above embodiments by those ordinary skilled in the art within the scope of the present disclosure.

1. A display panel, comprising:
a base substrate;
a backplane circuit layer disposed on a side of the base substrate;
light-emitting units arranged at intervals on a side of the backplane circuit layer away from the base substrate, wherein each of the light-emitting units comprises an anode, a light-emitting layer, and a cathode arranged sequentially in a direction pointing away from the backplane circuit layer, the cathodes of the light-emitting units are arranged at intervals, and the light-emitting layers of the light-emitting units are arranged at intervals; and
an auxiliary cathode located between the base substrate and the cathodes, and electrically connected with the cathodes.

2. The display panel according to claim 1, wherein the auxiliary cathode is a part of a source-drain electrode layer of the backplane circuit layer.

3. The display panel according to claim 1, wherein an orthographic projection of the anode onto the base substrate is located within an orthographic projection of the cathode onto the base substrate, and an orthographic projection of the auxiliary cathode onto the base substrate is located within the orthographic projection of the cathode onto the base substrate.

4. The display panel according to claim 1, wherein each of the light-emitting units further comprises a hole injection layer, a hole transport layer, an electron transport layer, and an electron injection layer;
wherein the hole injection layer is disposed between the anode and the light-emitting layer, the hole transport layer is disposed between the hole injection layer and the light-emitting layer, the electron transport layer is disposed between the light-emitting layer and the cathode, and the electron injection layer is disposed between the electron transport layer and the cathode; and
wherein the hole injection layers of the light-emitting units are arranged at intervals, the hole transport layers of the light-emitting units are arranged at intervals, the electron transport layers of the light-emitting units are arranged at intervals, and the electron injection layers of the light-emitting units are arranged at intervals.

5. The display panel according to claim 1, wherein each of the light-emitting units comprises sub-light-emitting units, each of which comprises a sub-cathode, a sub-anode, and a sub-light-emitting layer disposed between the sub-cathode and the sub-anode; and
wherein in each of the light-emitting units, the sub-anodes are arranged at intervals, the sub-light-emitting layers are arranged at intervals, and the sub-cathodes are joined with each other to form the cathode.

6. The display panel according to claim 5, wherein each of the sub-light-emitting units further comprises a sub-hole injection layer, a sub-hole transport layer, a sub-electron transport layer, and a sub-electron injection layer;
wherein the sub-hole injection layer is disposed between the sub-anode and the sub-light-emitting layer, the sub-hole transport layer is disposed between the sub-hole injection layer and the sub-light-emitting layer, the sub-electron transport layer is disposed between the sub-light-emitting layer and the sub-cathode, and the sub-electron injection layer is disposed between the sub-electron transport layer and the sub-cathode; and
wherein in each of the light-emitting units, the sub-hole injection layers are arranged at intervals, the sub-hole transport layers are arranged at intervals, the sub-electron transport layers are arranged at intervals, and the sub-electron injection layers are arranged at intervals.

7. The display panel according to claim 5, wherein each of the sub-light-emitting units further comprises a sub-hole injection layer, a sub-hole transport layer, a sub-electron transport layer, and a sub-electron injection layer;
wherein the sub-hole injection layer is disposed between the sub-anode and the sub-light-emitting layer, the sub-hole transport layer is disposed between the sub-hole injection layer and the sub-light-emitting layer, the sub-electron transport layer is disposed between the sub-light-emitting layer and the sub-cathode, and the sub-electron injection layer is disposed between the sub-electron transport layer and the sub-cathode; and
wherein in each of the light-emitting units, the sub-hole injection layers are joined with each other, the sub-hole transport layers are joined with each other, the sub-electron injection layers are joined with each other, and the sub-electron transport layers are joined with each other.

8. The display panel according to claim 5, wherein in each of the light-emitting units, a distance between the sub-anodes in adjacent two of the sub-light-emitting units is 5 μm to 15 μm.

9. The display panel according to claim 1, further comprising:
a bridge connecting the cathodes in adjacent two of the light-emitting units, and arranged in a same layer as the cathodes.

10. The display panel according to claim 9, wherein the bridge is elongated in shape, and has a width of 50 μm to 70 μm.

11. The display panel according to claim 10, wherein an orthographic projection of the auxiliary cathode onto the base substrate is located within an orthographic projection of the bridge onto the base substrate.

12. The display panel according to claim 1, wherein the backplane circuit layer comprises:
an active layer disposed on the side of the base substrate;
a gate insulation layer disposed on a side of the active layer away from the base substrate;
a gate electrode disposed on a side of the gate insulation layer away from the active layer;
an interlayer dielectric layer disposed on a side of the gate electrode away from the base substrate, and covering a surface of the gate insulation layer that is not covered by the gate electrode;
a source-drain electrode layer disposed on a side of the interlayer dielectric layer away from the base substrate, and electrically connected with the active layer; and
a planarization layer disposed on a side of the source-drain electrode layer away from the base substrate, and covering a surface of the interlayer dielectric layer that is not covered by the source-drain electrode layer.

13. The display panel according to claim 1, wherein the light-emitting units are arranged in an array;
wherein among the light-emitting units in a same row, a distance between two adjacent light-emitting units is equal to a width of the light-emitting unit in a row direction; and
wherein among the light-emitting units in a same column, a distance between two adjacent light-emitting units is equal to a width of the light-emitting unit in a column direction.

14. A method of manufacturing a display panel, comprising:
preparing a backplane circuit layer on a side of a base substrate;
forming light-emitting units arranged at intervals on a side of the backplane circuit layer away from the base substrate,
wherein forming the light-emitting units comprises:
forming anodes on the side of the backplane circuit layer away from the base substrate,
forming light-emitting layers on a side of the anodes away from the backplane circuit layer, and
forming cathodes on a side of the light-emitting layers away from the anodes,
wherein the cathodes are arranged at intervals, and the light-emitting layers are arranged at intervals; and
forming an auxiliary cathode between the base substrate and the cathodes, and electrically connecting the auxiliary cathode with the cathodes.

15. The method according to claim 14, wherein forming the light-emitting units comprises:
forming sub-anodes arranged at intervals on the side of the backplane circuit layer away from the base substrate;
forming sub-light-emitting layers arranged at intervals on a side of the sub-anodes away from the backplane circuit layer; and
forming sub-cathodes on a side of the sub-light-emitting layers away from the sub-anodes, the sub-cathodes being joined with each other to form the cathodes.

16. The method according to claim 14, wherein the auxiliary cathode is electrically connected with the cathodes through a connecting wire;
wherein the anodes and the light-emitting layers are formed by evaporation using a patterned mask; and
wherein the cathodes and the connecting wire are formed simultaneously by evaporation using a patterned mask.

17. The method according to claim 14, further comprising:
forming a bridge in a same step as the cathodes to connect the cathodes in adjacent two of the light-emitting units.

18. A display apparatus, comprising the display panel according to claim 1.

19. The display panel according to claim 12, wherein the planarization layer is made of colorless polyimide.

20. The display apparatus according to claim 18, wherein each of the light-emitting units comprises sub-light-emitting units, each of which comprises a sub-cathode, a sub-anode, and a sub-light-emitting layer disposed between the sub-cathode and the sub-anode; and
wherein in each of the light-emitting units, the sub-anodes are arranged at intervals, the sub-light-emitting layers are arranged at intervals, and the sub-cathodes are joined with each other to form the cathode.
